(19) United States
(12) Patent Application Publication
(10) Pub. No.: US 2004/0235241 A1
(43) Pub. Date: Nov. 25, 2004

(54) Method of manufacturing semiconductor device having capacitor

(75) Inventors: Masatoshi Anma, Tokyo (JP); Masahiko Takeuchi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/793,867

(22) Filed: Mar. 8, 2004

(30) Foreign Application Priority Data
May 22, 2003 (JP) 2003-144621

(51) Int. Cl. H01L 21/8242

(52) U.S. Cl. 438/239

(57) ABSTRACT

It is an object to obtain a method of manufacturing a semiconductor device having a capacitor capable of avoiding generation of a leakage current and an electrical short circuit between electrodes which are caused by a sharp portion of a lower electrode of the capacitor and a deterioration in a crystallinity of a dielectric film of the capacitor which is caused by a residue. A surface of a ruthenium film (7) is oxidized by a low temperature plasma oxidation process to form a ruthenium oxide film (9). Also in the case in which a part of a residue (51) exists on the surface of the ruthenium film (7), the existing residue (51) is lifted off and disappears by formation of the ruthenium oxide film (9) containing RuO₄ having a high vapor pressure in a large amount. The low temperature plasma oxidation process, moreover, has an anisotropy an oxidation rate in a vertical direction is higher than that in a transverse direction. Accordingly, an upper end of a side wall portion of the ruthenium film (7) is greatly oxidized in the vertical direction and is thus rounded. As a result, a sharp portion (50) disappears.

### BACKGROUND OF THE INVENTION

1. Field of the Invention

The present invention relates to a method of manufacturing a semiconductor device such as a DRAM having a capacitor.

2. Description of the Background Art

In a method of manufacturing a capacitor according to the conventional art, there have sequentially been executed the steps of (a) forming a concave portion in an upper surface of an interlayer insulating film, (b) wholly forming a ruthenium film over a structure obtained at the step (a), (c) filling the concave portion having the ruthenium film formed therein with an organic type material such as photoresist, (d) removing the ruthenium film in a portion formed on the upper surface of the interlayer insulating film by an etch back process, thereby forming a lower electrode of a capacitor, (e) removing a residue resulting from decomposition of the organic type material by a catalytic action of ruthenium, (f) wholly forming a tantalum oxide film to function as a dielectric film of the capacitor over a structure obtained at the step (e), and (g) wholly forming a ruthenium film to function as an upper electrode of the capacitor over a structure obtained at the step (f).

A technology related to the method of manufacturing a capacitor has been disclosed in Japanese Patent Application Laid-Open No. 2002-198498, Japanese Patent Application Laid-Open No. 2002-217375, Japanese Patent Application Laid-Open No. 2000-196042 and Japanese Patent Application Laid-Open No. 2002-9046.

According to the method of manufacturing a capacitor in accordance with the conventional art, however, the ruthenium film is etched back at the step (d) so that a sharp portion is generated on an upper end of a side wall of the lower electrode of the capacitor. There is a problem in that a leakage current is generated through the dielectric film of the capacitor between the upper and lower electrodes of the capacitor due to a convergence of an electric field which is generated in the sharp portion. Moreover, there is also a problem in that the sharp portion is broken in the middle of the manufacturing steps and the broken sharp portion causes the lower electrodes of the capacitor to be electrically short-circuited between two adjacent memory cells to each other and the upper and lower electrodes of the capacitor in one memory cell to be electrically short-circuited.

According to the method of manufacturing a capacitor in accordance with the conventional art, furthermore, in the case in which the residue is removed incompletely at the step (e) and a part of the residue exists on a surface of the lower electrode of the capacitor, there is also a problem in that a crystallinity of the dielectric film of the capacitor formed on the lower electrode of the capacitor is deteriorated due to the existing residue.

### SUMMARY OF THE INVENTION

It is an object of the present invention to obtain a method of manufacturing a semiconductor device having a capacitor capable of avoiding generation of a leakage current and an electrical short circuit between electrodes which are caused by a sharp portion of a lower electrode of the capacitor and a deterioration in a crystallinity of a dielectric film of the capacitor which is caused by a residue.

According to a first aspect of the present invention, a method of manufacturing a semiconductor device having a capacitor includes the following steps (a) to (d). At the step (a), a concave portion is formed in a main surface of an insulating film provided on a substrate. At the step (b), a lower electrode of a capacitor is formed on a side surface and a bottom surface of the concave portion. At the step (c), a surface of the lower electrode of the capacitor is oxidized by a plasma oxidation process in which an oxidation rate in a direction of a depth of the concave portion is higher than that in a plane direction of an opening surface of the concave portion so that an oxide film is formed. The step (d) is executed after the step (c). At the step (d), an upper electrode of the capacitor opposed to the lower electrode of the capacitor is formed with a dielectric film of the capacitor interposed therebetween.

It is possible to avoid generation of a leakage current and an electrical short circuit between electrodes.

According to a second aspect of the present invention, a method of manufacturing a semiconductor device having a capacitor includes the following steps (a) to (f). At the step (a), a concave portion is formed in a main surface of an insulating film provided on a substrate. At the step (b), a metal film is formed on a side surface and a bottom surface of the concave portion and the main surface of the insulating film. At the step (c), the concave portion provided with the metal film is filled with an organic type material. The step (d) is executed after the step (c). At the step (d), the metal film in a portion formed on the main surface of the insulating film is removed so that a lower electrode of a capacitor is formed. At the step (e), a surface of the lower electrode of the capacitor is oxidized by a low temperature plasma oxidation process so that an oxide film is formed. At the step (f), an upper electrode of the capacitor opposed to the lower electrode of the capacitor is formed with a dielectric film of the capacitor interposed therebetween.

It is possible to avoid a deterioration in a crystallinity of the dielectric film of the capacitor.

According to a third aspect of the present invention, a method of manufacturing a semiconductor device having a capacitor includes the following steps (a) to (e). At the step (a), a concave portion is formed in a main surface of an insulating film provided on a substrate. At the step (b), a metal film belonging to a platinum group is formed on a side surface and a bottom surface of the concave portion and the main surface of the insulating film. At the step (c), the concave portion provided with the metal film is filled with an inorganic type material. The step (d) is executed after the step (c). At the step (d), the metal film in a portion formed on the main surface of the insulating film is removed so that a lower electrode of a capacitor is formed. At the step (e), an upper electrode of the capacitor opposed to the lower electrode of the capacitor is formed with a dielectric film of the capacitor interposed therebetween.

It is possible to avoid a deterioration in a crystallinity of the dielectric film of the capacitor.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 12 are sectional views showing a method of manufacturing a capacitor according to a first preferred embodiment of the present invention in order of steps,

FIGS. 13 to 17 are sectional views showing a method of manufacturing a capacitor according to a second preferred embodiment of the present invention in order of steps, and

FIGS. 18 to 21 are sectional views showing a method of manufacturing a capacitor according to a third preferred embodiment of the present invention in order of steps.

### DESCRIPTION OF THE PREFERRED EMBODIMENTS

### First Preferred Embodiment

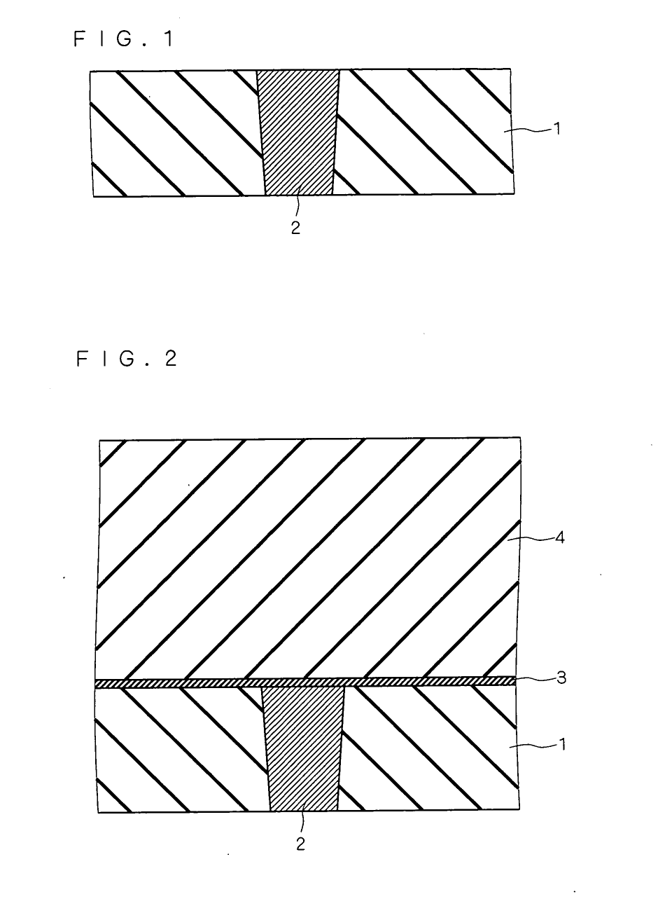

FIGS. 1 to 12 are sectional views showing a method of manufacturing a capacitor according to a first preferred embodiment of the present invention in order of steps. With reference to FIG. 1, first of all, a contact plug 2 is formed in a silicon oxide film 1. The silicon oxide film 1 functions as an interlayer insulating film and is formed on a silicon substrate (not shown) to cover a memory cell transistor and a bit line (not shown). The contact plug 2 is formed of tungsten, for example, and is connected to source/drain region of the memory cell transistor.

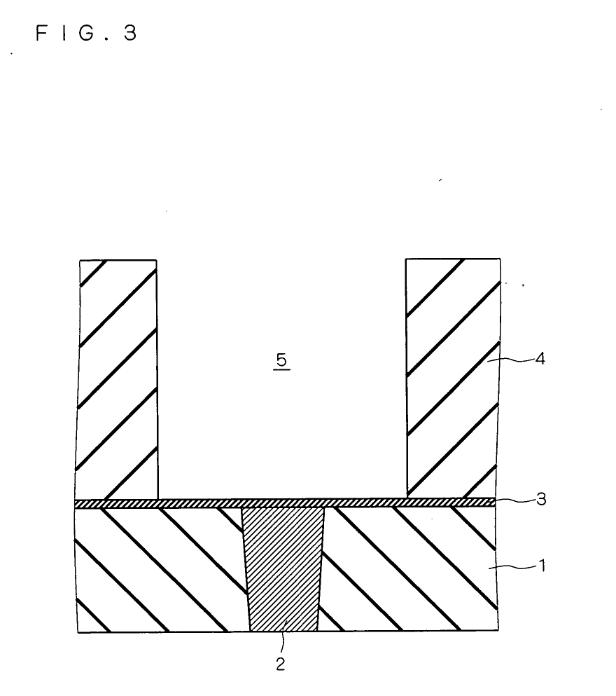

With reference to FIG. 2, next, a silicon nitride film 3 is wholly formed over the structure shown in FIG. 1 by a CVD process. Then, a silicon oxide film 4 is wholly formed on the silicon nitride film 3 by the CVD process. The silicon oxide film 4 functions as an interlayer insulating film.

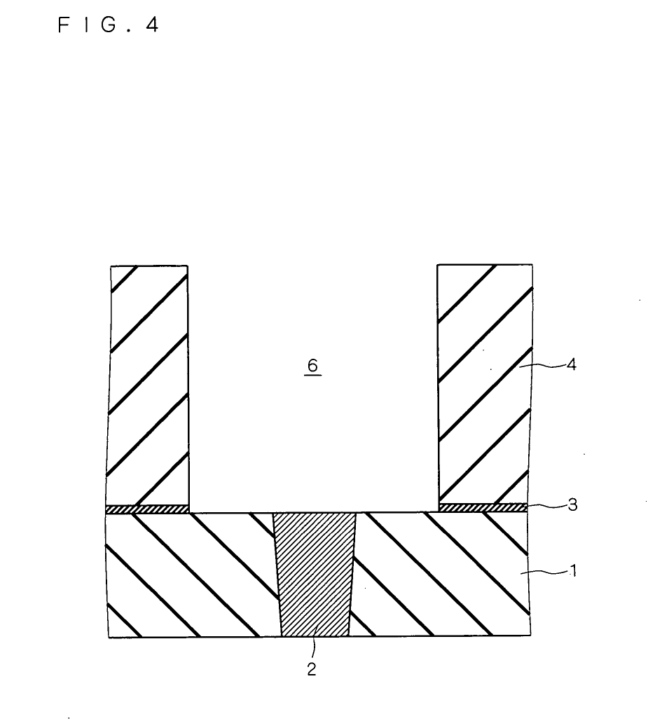

With reference to FIG. 3, thereafter, the silicon oxide film 4 is partially removed by a photolithographic process and an anisotropic dry etching process so that a concave portion 5 is formed. At the step of etching the silicon oxide film 4, the silicon nitride film 3 functions as an etching stopper. The concave portion 5 has a side surface defined by the silicon oxide film 4 and a bottom surface defined by the silicon nitride film 3.

With reference to FIG. 4, subsequently, the silicon nitride film 3 in a portion defining the bottom surface of the concave portion 5 is removed to form a concave portion 6. The concave portion 6 has a side surface defined by the silicon oxide film 4 and the silicon nitride film 3 and a bottom surface defined by the contact plug 2 and the silicon oxide film 1.

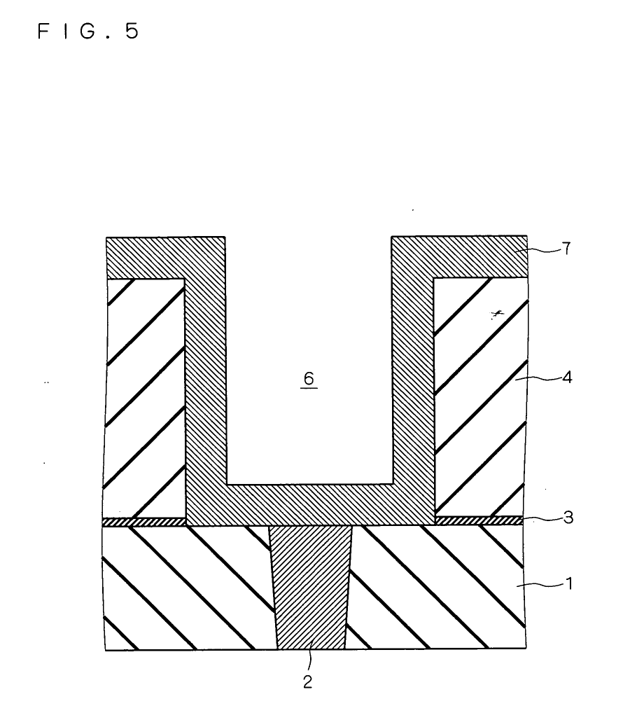

With reference to FIG. 5, next, a ruthenium film having a film thickness of approximately 40 nm is wholly formed over the structure shown in FIG. 4 by the CVD process or a PVD process. Then, the ruthenium film is crystallized by a heat treatment to form a ruthenium film 7. The ruthenium film 7 is formed on an upper surface of the silicon oxide film 4 and the side surface and bottom surface of the concave portion 6.

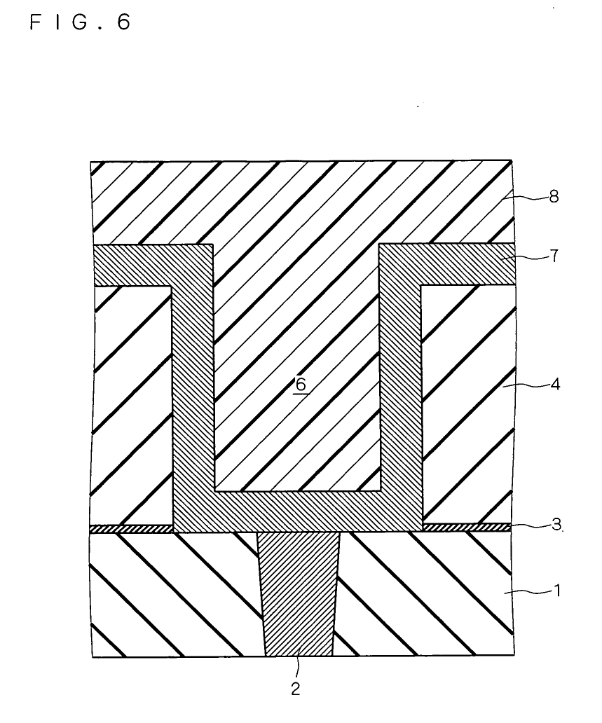

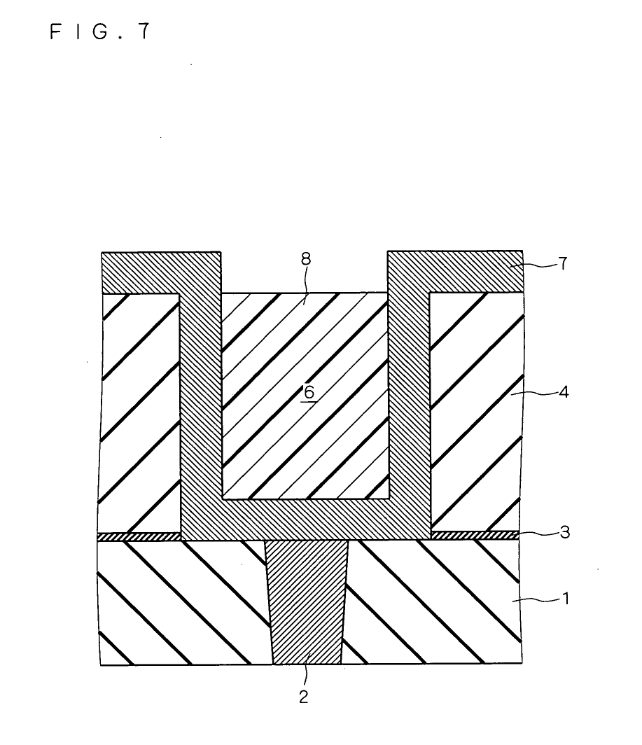

With reference to FIG. 6, thereafter, an organic type material 8 such as photoresist or organic SOG is wholly applied onto the structure shown in FIG. 5. The organic type material 8 is formed to completely fill up the concave portion 6 provided with the ruthenium film 7. Moreover, the organic type material 8 is also formed on the ruthenium film 7 in a portion provided on the upper surface of the silicon oxide film 4.

With reference to FIG. 7, next, the organic type material 8 is partially removed by the photolithographic process or by rotating a wafer at a high speed and is left in only the concave portion 6. The organic type material 8 filled in the concave portion 6 plays a part in protecting the ruthenium film 7 when the ruthenium film 7 is to be etched back at a subsequent step.

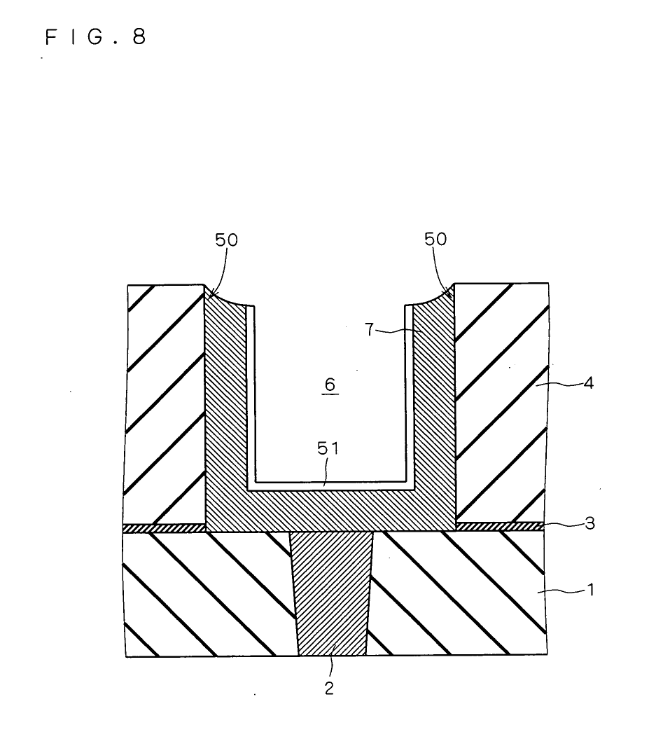

With reference to FIG. 8, then, the ruthenium film 7 in a portion present above the upper surface of the silicon oxide film 4 is removed by a dry etch back process. Moreover, the organic type material 8 is removed. Consequently, the ruthenium film 7 is isolated between two adjacent memory cells to each other. As shown in FIG. 8, the ruthenium film 7 has a portion formed on the side surface of the concave portion 6 (which will be hereinafter referred to as a “side wall portion”) and a portion formed on the bottom surface of the concave portion 6 (which will be hereinafter referred to as a “bottom portion”). A sharp portion 50 is generated on an upper end in the side wall portion of the ruthenium film 7. Moreover, the organic type material 8 is decomposed by a catalytic action of the ruthenium so that a residue 51 is generated on a surface of the ruthenium film 7.

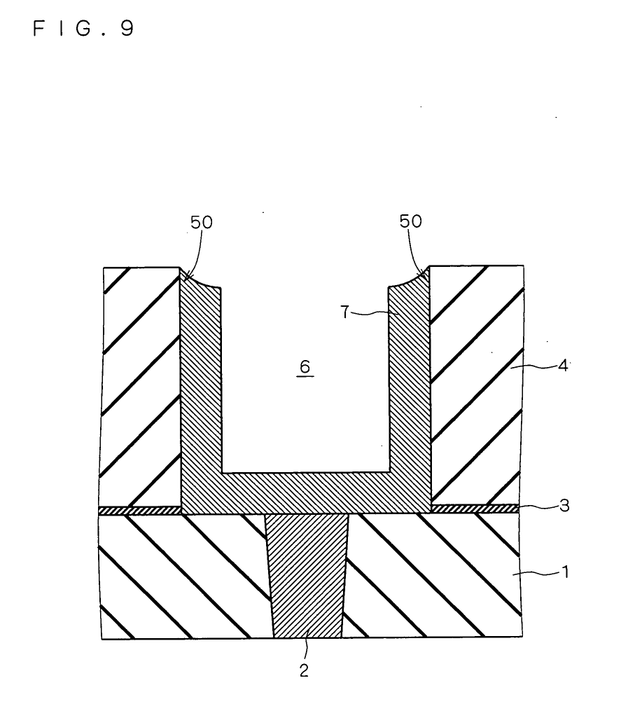

With reference to FIG. 9, thereafter, the residue 51 is removed. In the case in which the organic type material 8 is photoresist, the residue 51 can be removed by using an organic solvent such as thinner or a mixed solution of H₂SO₄ and H₂O₂. In the case in which the organic type material 8 is organic SOG, the residue 51 can be removed by a dilute fluoric acid solution or a gas phase reaction of fluoric acid.

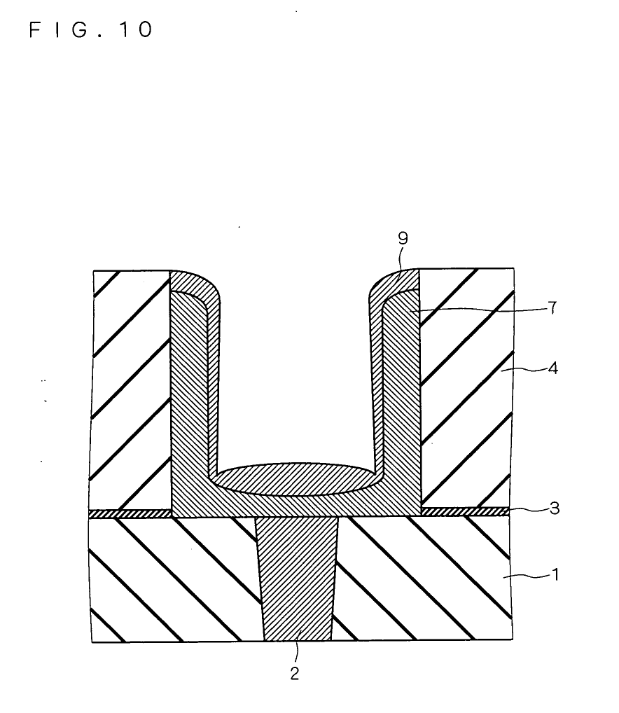

With reference to FIG. 10, subsequently, a surface of the ruthenium film 7 is oxidized by a low temperature plasma oxidation process in which a surface temperature of a wafer is approximately 20 to 250° C. (desirably 40 to 180° C.). Consequently, a conductive ruthenium oxide film 9 is formed.

Because of an oxidation process at a low temperature, more RuO₄ having a high vapor pressure is produced than RuO₂ having a low vapor pressure. Also in the case in which the residue 51 is incompletely removed at the step shown in FIG. 9 and a part of the residue 51 exists on the surface of the ruthenium film 7, accordingly, the existing residue 51 is lifted off and disappears by the RuO₄ having a high vapor pressure.

Moreover, the low temperature plasma oxidation process has an anisotropy an oxidation rate in a vertical direction is higher than that in a transverse direction. The “transverse direction” implies a plane direction of an opening surface of the concave portion 6 and the “vertical direction” implies a direction of a depth of the concave portion 6. As shown in FIG. 10, accordingly, the upper end in the side wall portion of the ruthenium film 7 is greatly oxidized in the vertical direction and is thus rounded. As a result, the sharp portion 50 disappears. Furthermore, an amount of oxidation in the vertical direction in the bottom portion of the ruthenium film 7 is much larger than that in the transverse direction in the side wall portion of the ruthenium film 7. Consequently, the bottom portion of the ruthenium film 7 is wholly rounded in such a manner that a film thickness is gradually reduced from a peripheral portion toward a central portion. Owing to this shape, it is possible to prevent a convergence of an electric field from being generated in the bottom portion of the ruthenium film 7.

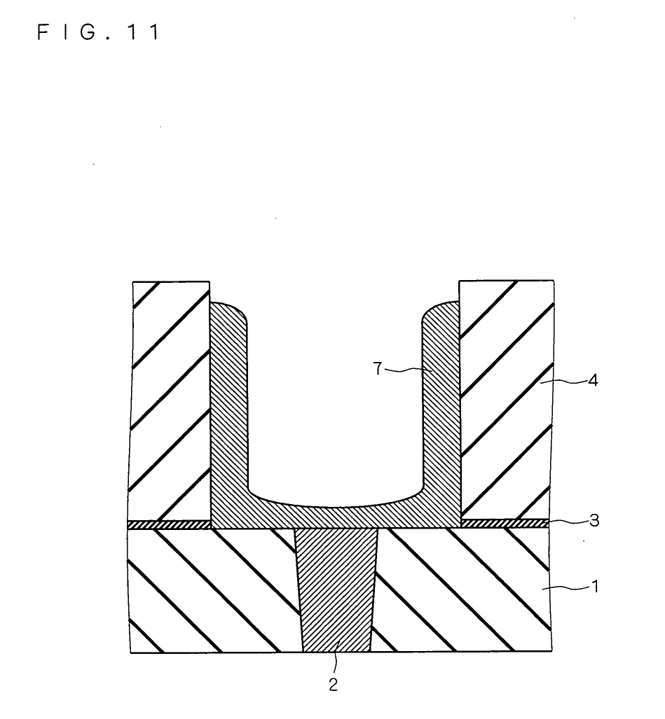

With reference to FIG. 11, next, a heat treatment is carried out in an atmosphere in which hydrogen is contained and a pressure is reduced to approximately 1 mTorr to 750 Torr. Thus, the ruthenium oxide film 9 is reduced. By the reduction of the ruthenium oxide film 9, the ruthenium is obtained. By a volumetric shrinkage in the reduction, the shape of the bottom portion of the ruthenium film 7 (that is, a wholly rounded shape) is maintained. In FIG. 11, the ruthenium obtained by the reduction is included in the ruthenium film 7. The ruthenium film 7 obtained after the reduction of the ruthenium oxide film 9 functions as a lower electrode of a capacitor. Depending on a type of a dielectric film of the capacitor which will be formed later, the reduction of the ruthenium oxide film 9 is not required. In this case, the ruthenium film 7 and the ruthenium oxide film 9 function as the lower electrode of the capacitor.

In the case in which the residue 51 is removed incompletely at the step shown in FIG. 9 and the existing residue 51 does not completely disappear by the formation of the ruthenium oxide film 9, the same processing as the processing executed at the step shown in FIG. 9 is carried out again after the ruthenium oxide film 9 is removed. Due to the formation of the ruthenium oxide film 9, a bonding strength of the residue 51 and the surface of the ruthenium film 7 is decreased. In addition, since the bottom portion of the ruthenium film 7 is wholly rounded, the existing residue 51 can easily be removed completely.

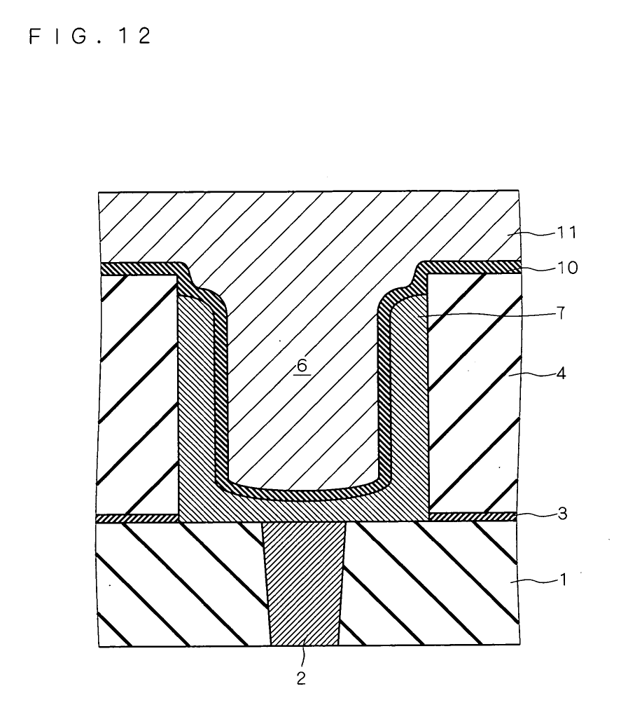

With reference to FIG. 12, next, a tantalum oxide film 10 is wholly formed over the structure shown in FIG. 11 by the CVD process. The tantalum oxide film 10 functions as the dielectric film of the capacitor. Then, a predetermined heat treatment is carried out in order to improve crystallization and quality of the tantalum oxide film 10. Thereafter, a ruthenium film 11 is wholly formed on the tantalum oxide film 10 by the CVD process. The ruthenium film 11 functions as an upper electrode of the capacitor and is opposed to the ruthenium film 7 with the tantalum oxide film 10 interposed therebetween. By the steps described above, the capacitor is completed.

According to the method of manufacturing a capacitor in accordance with the first preferred embodiment, thus, the surface of the ruthenium film 7 is oxidized by an oxidation process having an anisotropy at the step shown in FIG. 10. Consequently, the sharp portion 50 generated on the upper end in the side wall portion of the ruthenium film 7 disappears. Accordingly, it is possible to prevent a leakage current or an electrical short circuit between electrodes from being caused by the sharp portion 50.

Moreover, it is possible to completely remove the residue 51 existing on the surface of the ruthenium film 7. Therefore, it is possible to prevent the crystallinity of the dielectric film of the capacitor from being deteriorated by the residue 51.

### Second Preferred Embodiment

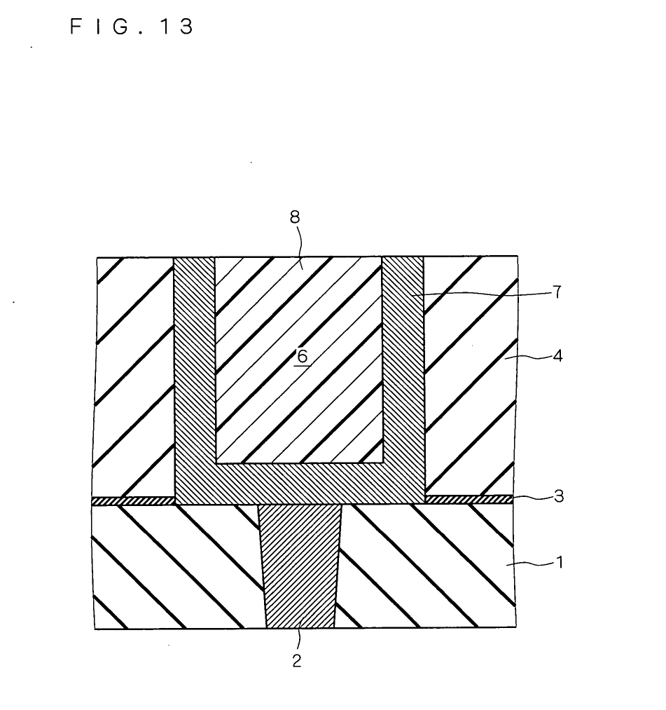

FIGS. 13 to 17 are sectional views showing a method of manufacturing a capacitor according to a second preferred embodiment of the present invention in order of steps. First of all, the structure shown in FIG. 6 is obtained through the same steps as those in the first preferred embodiment. In the second preferred embodiment, the organic type material 8 shown in FIG. 6 plays a part in preventing a slurry used in a CMP process from existing in the concave portion 6 when a part of the ruthenium film 7 is to be removed by the CMP process at a subsequent step.

With reference to FIG. 13, next, the organic type material 8 and the ruthenium film 7 in a portion present above an upper surface of a silicon oxide film 4 are removed by the CMP process. Consequently, the ruthenium film 7 is isolated between two adjacent memory cells to each other.

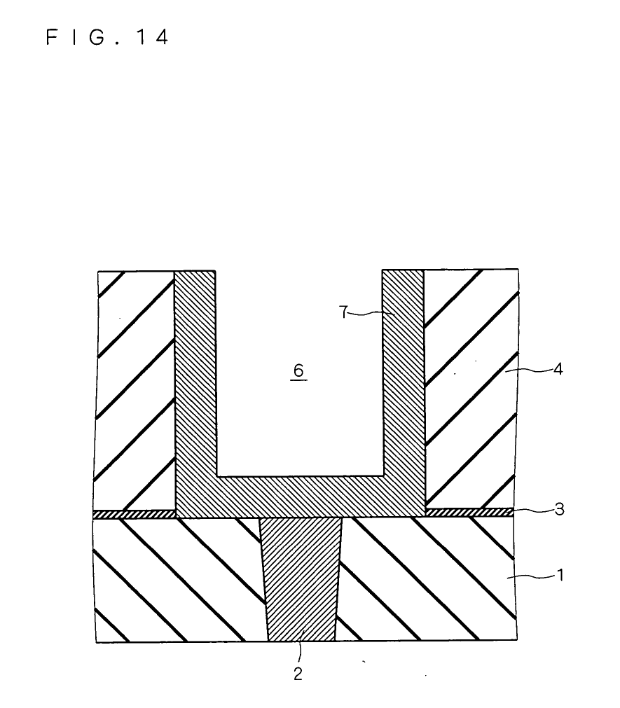

With reference to FIG. 14, then, the organic type material 8 is removed. Thereafter, a residue 51 generated on a surface of the ruthenium film 7 is removed by the same method as that in the first preferred embodiment.

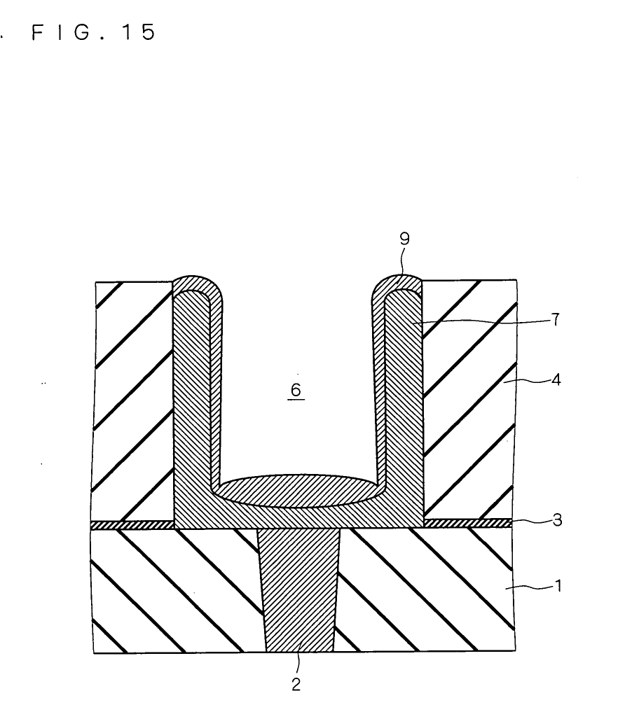

With reference to FIG. 15, subsequently, the surface of the ruthenium film 7 is oxidized by a low temperature plasma oxidation process in the same manner as in the first preferred embodiment to form a ruthenium oxide film 9. Also in the case in which the residue 51 is incompletely removed at the step shown in FIG. 14 and a part of the residue 51 exists on the surface of the ruthenium film 7, consequently, the existing residue 51 is lifted off and disappears. Moreover, a bottom portion of the ruthenium film 7 is wholly rounded in such a manner that a film thickness is gradually reduced from a peripheral portion toward a central portion.

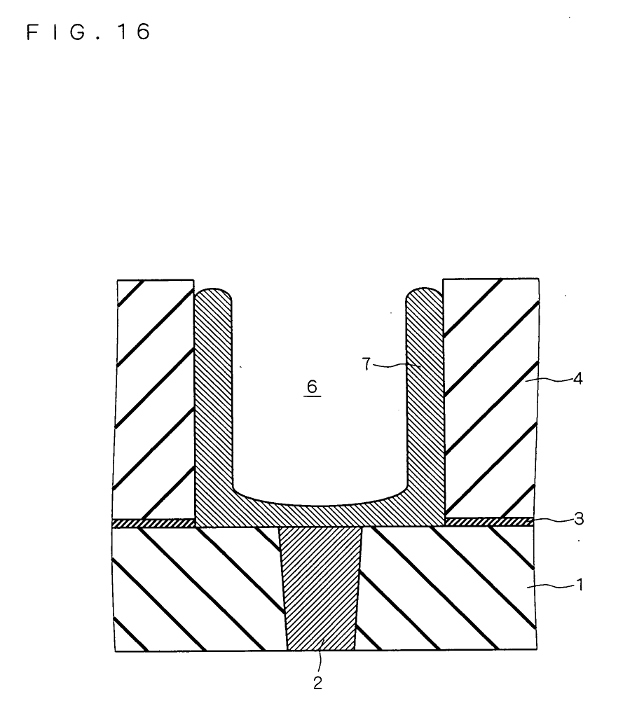

With reference to FIG. 16, next, a heat treatment is carried out in a predetermined atmosphere to reduce the ruthenium oxide film 9 in the same manner as in the first preferred embodiment. In the case in which the residue 51 is incompletely removed at the step shown in FIG. 14 and the existing residue 51 is not caused to completely disappear by the formation of the ruthenium oxide film 9, the processing of removing the residue 51 using an organic solvent is carried out again in the same manner as in the first preferred embodiment.

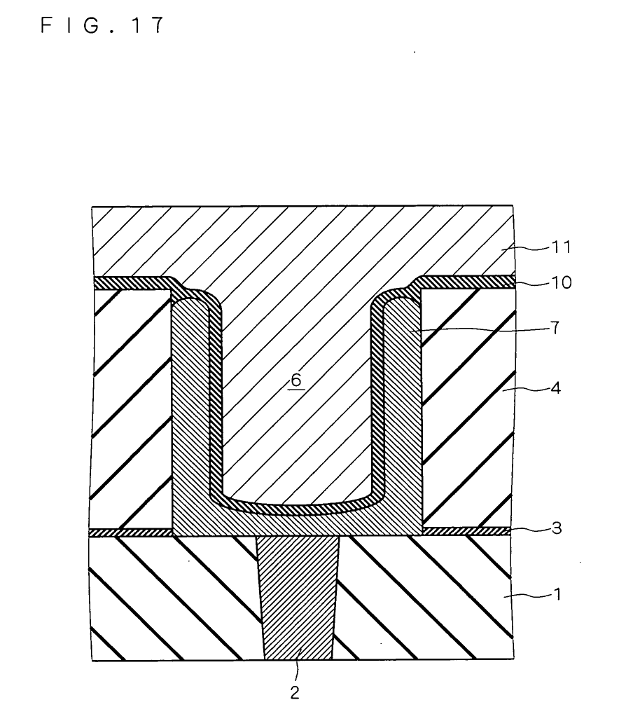

With reference to FIG. 17, then, a tantalum oxide film 10 is wholly formed over the structure shown in FIG. 16 by a CVD process. Thereafter, a predetermined heat treatment is carried out in order to improve crystallization and quality of the tantalum oxide film 10. Subsequently, a ruthenium film 11 is wholly formed on the tantalum oxide film 10 by the CVD process. By the steps described above, a capacitor is completed.

By the method of manufacturing a capacitor according to the second preferred embodiment in which a part of the ruthenium film 7 is removed by the CMP process in place of a dry etch back process, similarly, the same effects as those in the first preferred embodiment can be obtained.

### Third Preferred Embodiment

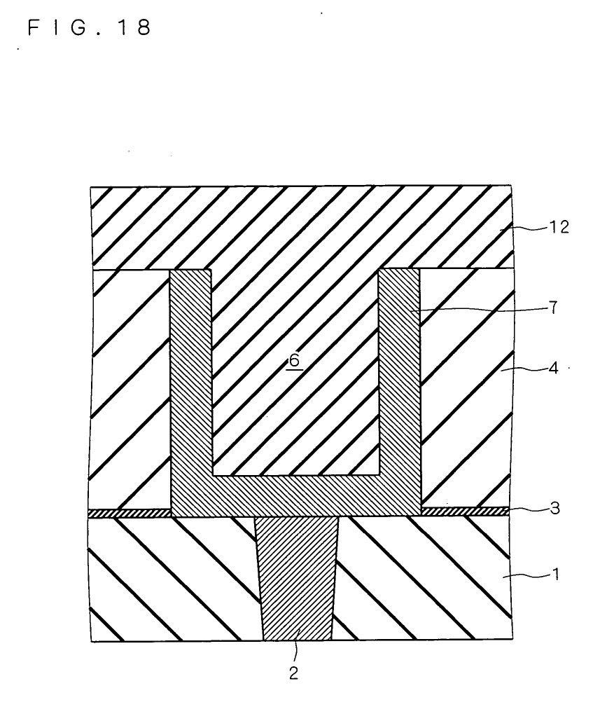

FIGS. 18 to 21 are sectional views showing a method of manufacturing a capacitor according to a third preferred embodiment of the present invention in order of steps. First of all, the structure shown in FIG. 5 is obtained through the same steps as those in the first preferred embodiment.

With reference to FIG. 18, an inorganic type material 12 such as silsesquioxane hydroxide or inorganic SOG is wholly applied onto the structure shown in FIG. 5. The inorganic type material 12 is formed to completely fill up a concave portion 6 provided with a ruthenium film 7. Moreover, the inorganic type material 12 is also formed on the ruthenium film 7 in a portion provided on an upper surface of a silicon oxide film 4. The inorganic type material 12 plays a part in preventing a slurry to be used in a CMP process from existing in the concave portion 6 when a part of the ruthenium film 7 is to be removed by the CMP process at a subsequent step.

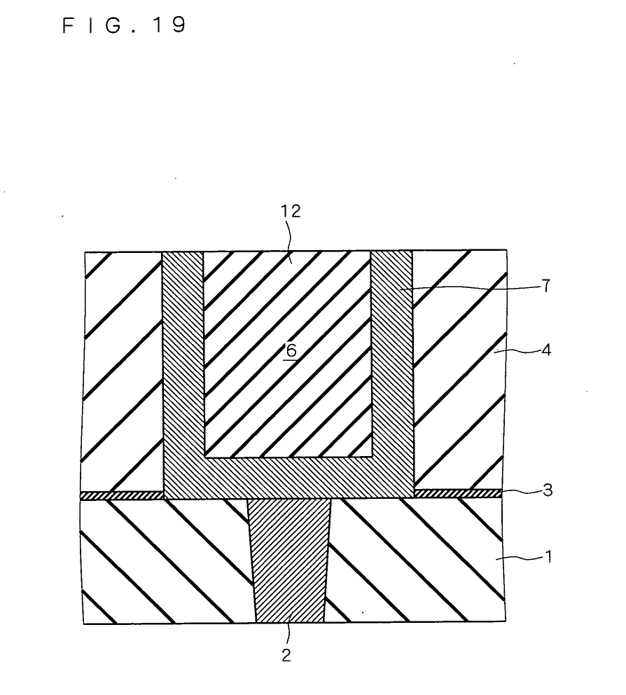

With reference to FIG. 19, next, the inorganic type material 12 and the ruthenium film 7 in the portion present above the upper surface of the silicon oxide film 4 are removed by the CMP process. Consequently, the ruthenium film 7 is isolated between two adjacent memory cells to each other.

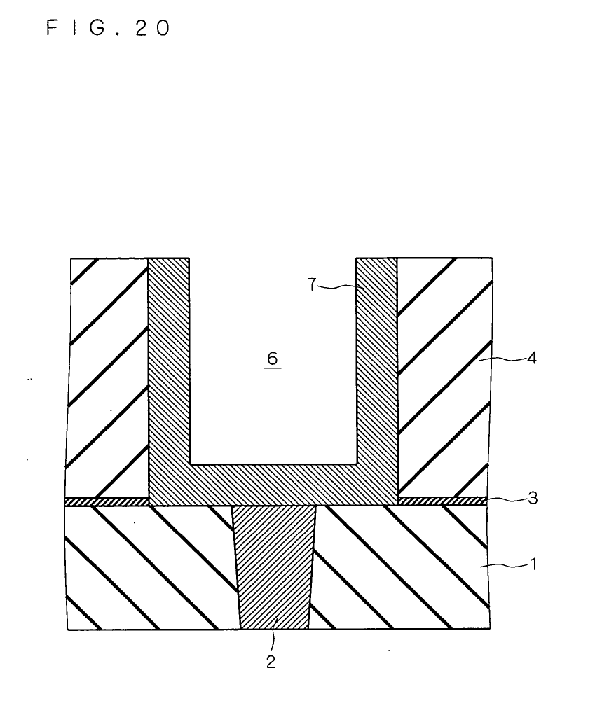

With reference to FIG. 20, then, the inorganic type material 12 is removed by a dilute fluoric acid solution or a vapor phase reaction of fluoric acid. The inorganic type material 12 is not decomposed by a catalytic action of ruthenium. Therefore, a residue 51 is not generated on a surface of the ruthenium film 7.

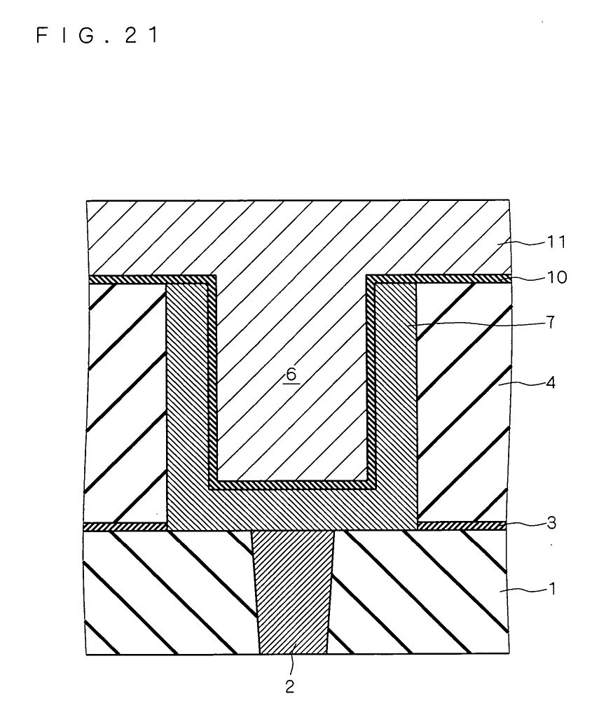

With reference to FIG. 21, thereafter, a tantalum oxide film 10 is wholly formed over the structure shown in FIG. 20 by a CVD process. Subsequently, a predetermined heat treatment is carried out in order to improve crystallization and quality of the tantalum oxide film 10. Next, a ruthenium film 11 is wholly formed on the tantalum oxide film 10 by the CVD process. By the steps described above, a capacitor is completed.

In the same manner as in the first and second preferred embodiments, the surface of the ruthenium film 7 may be oxidized by a low temperature plasma oxidation process to form a ruthenium oxide film 9. In addition, a heat treatment may be carried out in a predetermined atmosphere to reduce the ruthenium oxide film 9.

According to the method of manufacturing a capacitor in accordance with the third preferred embodiment, thus, the concave portion 6 provided with the ruthenium film 7 is filled with the inorganic type material 12 in place of the organic type material 8 at the step shown in FIG. 18. As a result, also in the case in which the ruthenium is used as a material of a lower electrode of the capacitor, the residue 51 is not generated. Therefore, it is possible to prevent a crystallinity of a dielectric film of the capacitor from being deteriorated by the residue 51.

While the description has been given to the case in which the material of the upper and lower electrodes of the capacitor is the ruthenium in the first to third preferred embodiments, the material of these electrodes may be a platinum group element such as platinum (Pt) or iridium (Ir). While the description has been given to the case in which the material of the dielectric film of the capacitor is tantalum oxide, moreover, the same material may be a high dielectric or a ferroelectric such as strontium titanate (STO) or barium strontium titanate (BST).

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device having a capacitor, comprising the steps of:
(a) forming a concave portion in a main surface of an insulating film provided on a substrate;
(b) forming a lower electrode of a capacitor on a side surface and a bottom surface of said concave portion;
(c) oxidizing a surface of said lower electrode of said capacitor by an oxidation process in which an oxidation rate in a direction of a depth of said concave portion is higher than that in a plane direction of an opening surface of said concave portion, thereby forming an oxide film; and
(d) forming an upper electrode of said capacitor opposed to said lower electrode of said capacitor with a dielectric film of said capacitor interposed therebetween after said step (c).

2. The method of manufacturing a semiconductor device having a capacitor according to claim 1, wherein said step (b) includes the steps of:
(b-1) forming a metal film on said side surface and bottom surface of said concave portion and said main surface of said insulating film;
(b-2) filling said concave portion provided with said metal film with an organic type material; and
(b-3) removing said metal film in a portion formed on said main surface of said insulating film after said step (b-2),
the method of manufacturing a semiconductor device having a capacitor further comprising the steps of:
(e) reducing said oxide film before said step (d); and
(f) removing a residue existing on said lower electrode of said capacitor after said step (e).

3. The method of manufacturing a semiconductor device having a capacitor according to claim 1, wherein said step (b) includes the steps of:
(b-1) forming a metal film on said side surface and bottom surface of said concave portion and said main surface of said insulating film;
(b-2) filling said concave portion provided with said metal film with an organic type material; and
(b-3) removing said metal film in a portion formed on said main surface of said insulating film after said step (b-2),
said oxide film being formed by a low temperature plasma oxidation process at said step (c).

4. The method of manufacturing a semiconductor device having a capacitor according to claim 1, wherein said step (b) includes the steps of:
(b-1) forming a metal film on said side surface and bottom surface of said concave portion and said main surface of said insulating film;
(b-2) filling said concave portion provided with said metal film with an inorganic type material; and
(b-3) removing said metal film in a portion formed on said main surface of said insulating film after said step (b-2).

5. A method of manufacturing a semiconductor device having a capacitor, comprising the steps of:
(a) forming a concave portion in a main surface of an insulating film provided on a substrate;
(b) forming a metal film on a side surface and a bottom surface of said concave portion and said main surface of said insulating film;
(c) filling said concave portion provided with said metal film with an organic type material;
(d) removing said metal film in a portion formed on said main surface of said insulating film, thereby forming a lower electrode of a capacitor after said step (c);
(e) oxidizing a surface of said lower electrode of said capacitor by a low temperature plasma oxidation process, thereby forming an oxide film; and
(f) forming an upper electrode of said capacitor opposed to said lower electrode of said capacitor with a dielectric film of said capacitor interposed therebetween.

6. A method of manufacturing a semiconductor device having a capacitor, comprising the steps of:
(a) forming a concave portion in a main surface of an insulating film provided on a substrate;
(b) forming a metal film belonging to a platinum group on a side surface and a bottom surface of said concave portion and said main surface of said insulating film;
(c) filling said concave portion provided with said metal film with an inorganic type material;
(d) removing said metal film in a portion formed on said main surface of said insulating film, thereby forming a lower electrode of a capacitor after said step (c); and
(e) forming an upper electrode of said capacitor opposed to said lower electrode of said capacitor with a dielectric film of said capacitor interposed therebetween.
